(19) United States
(12) Patent Application Publication
(10) Pub. No.: US 2025/0298090 A1
(43) Pub. Date: Sep. 25, 2025

(54) ELECTRONIC APPARATUS, NON-TRANSITORY COMPUTER READABLE MEDIUM STORING PROGRAM, AND METHOD

(71) Applicant: FUJIFILM Business Innovation Corp., Tokyo (JP)

(72) Inventor: Hidefumi NISHIGAI, Kanagawa (JP)

(73) Assignee: FUJIFILM Business Innovation Corp., Tokyo (JP)

(21) Appl. No.: 18/779,107

(22) Filed: Jul. 22, 2024

(30) Foreign Application Priority Data
Mar. 21, 2024 (JP) 2024-045741

(51) Int. Cl. G01R 31/55; G01R 31/52; H02H 5/10

(52) U.S. Cl. CPC G01R 31/55; G01R 31/52; H02H 5/105

(57) ABSTRACT

An electronic apparatus includes a detection unit that detects a magnitude of a noise component superimposed on a metal frame of an apparatus body and a processor configured to notify that there is a possibility that an earth wire will not be in a correct connection state in a case where the magnitude of the noise component detected by the detection unit exceeds a preset threshold value.

### CROSS-REFERENCE TO RELATED APPLICATIONS

This application is based on and claims priority under 35 USC 119 from Japanese Patent Application No. 2024-045741 filed Mar. 21, 2024.

### BACKGROUND

### (i) Technical Field

The present disclosure relates to an electronic apparatus, a non-transitory computer readable medium storing a program, and a method.

### (ii) Related Art

JP2018-107866A discloses an image forming apparatus that uses a 200-V alternating current power supply as a commercial power supply for operating the apparatus.

### SUMMARY

In various apparatuses that are operated by a commercial power supply, in some cases, it is necessary to connect an earth wire of an apparatus body to a D-class ground in order to prevent a human body from receiving an electric shock in a case where a leakage of electricity occurs. In particular, in an electronic apparatus using a single-phase 200-V alternating current power supply, a voltage generated in a case of a leakage of electricity is also increased. Therefore, it is more crucial to connect the earth wire of the apparatus body to the D-class ground. However, even in a case of a non-connection state in which the earth wire of the apparatus body is not connected to the D-class ground, the electronic apparatus is operated normally as long as the leakage of electricity does not occur. Therefore, it is difficult to ascertain whether or not the earth wire of the apparatus body is correctly connected to the D-class ground. In addition, in a case where the earth wire on the body side is incorrectly connected to a neutral wire of a single-phase three-wire system or a ground-side electric circuit of a three-phase three-wire system, there is a possibility that the ground voltage of the electronic apparatus will increase due to a neutral wire open phase failure, an insulation failure on the power supply facility side, or the like and thus an electric shock accident will occur.

Aspects of non-limiting embodiments of the present disclosure relate to an electronic apparatus, a non-transitory computer readable medium storing a program, and a method that can ascertain whether or not an earth wire of an apparatus body is in a correct connection state.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided an electronic apparatus including: a detection unit that detects a magnitude of a noise component superimposed on a metal frame of an apparatus body; and a processor configured to notify that there is a possibility that an earth wire will not be in a correct connection state in a case where the magnitude of the noise component detected by the detection unit exceeds a preset threshold value.

### BRIEF DESCRIPTION OF THE DRAWINGS

Exemplary embodiment(s) of the present invention will be described in detail based on the following figures, wherein:

FIG. 1 is a diagram illustrating a system configuration of an image forming system according to an exemplary embodiment of the present disclosure;

FIG. 2 is a diagram illustrating a correct connection state in a case where single-phase three-wire 200 V is used as a power supply;

FIG. 3 is a diagram illustrating a wiring state for implementing the correct connection state illustrated in FIG. 2;

FIG. 4 is a diagram illustrating a non-connection state of an earth wire as an example of an incorrect connection state in a case where single-phase three-wire 200 V is used as the power supply;

FIG. 5 is a diagram illustrating an incorrect wiring state in a case where single-phase three-wire 200 V is used as the power supply;

FIG. 6 is a diagram illustrating a connection state in a case where a power plug of an image forming apparatus 10 is connected to an outlet 53 in the wiring state illustrated in FIG. 5;

FIG. 7 is a diagram illustrating an aspect in which a neutral wire open phase occurs in the incorrect connection state illustrated in FIG. 6;

FIG. 8 is a diagram illustrating a correct connection state in a case where three-phase three-wire 200 V is used as the power supply;

FIG. 9 is a diagram illustrating an incorrect connection state in a case where three-phase three-wire 200 V is used as the power supply;

FIG. 10 is a block diagram illustrating a hardware configuration of the image forming apparatus 10 according to the exemplary embodiment of the present disclosure;

FIG. 11 is a block diagram illustrating a functional configuration of the image forming apparatus 10 according to the exemplary embodiment of the present disclosure;

FIG. 12 is a diagram illustrating a configuration of a noise detection unit 18 illustrated in FIG. 11;

FIG. 13A is a diagram illustrating an aspect of noise superimposed on a metal frame 22 in a case where the earth wire is not correctly connected, and FIG. 13B is a diagram illustrating an aspect of the noise superimposed on the metal frame 22 in a case where the earth wire is correctly connected; and

FIG. 14 is a diagram illustrating an example of a warning screen displayed on an operation panel 34 by a control unit 33 in a case where it is determined that there is a possibility that the earth wire 21 will not be in the correct connection state.

### DETAILED DESCRIPTION

Hereinafter, an exemplary embodiment of the present disclosure will be described in detail with reference to the drawings.

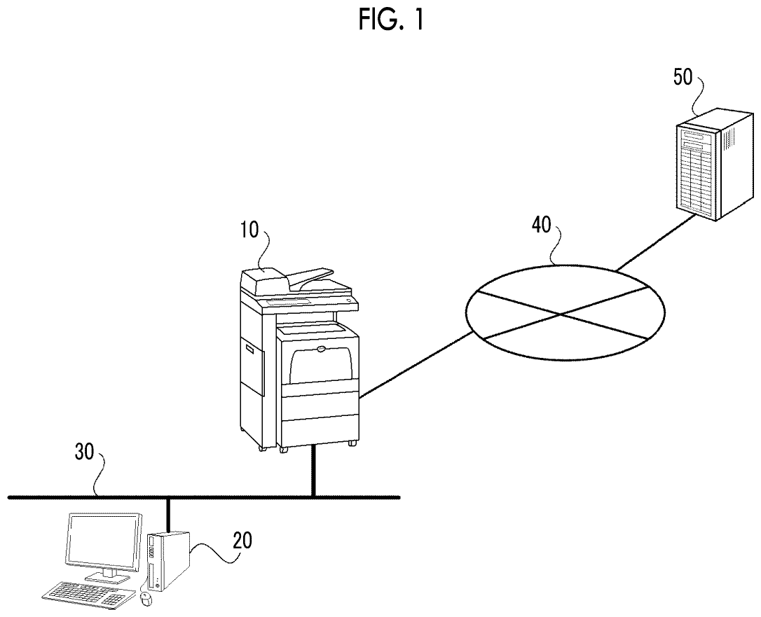

FIG. 1 is a diagram illustrating a system configuration of an image forming system according to an exemplary embodiment of the present disclosure.

As illustrated in FIG. 1, the image forming system according to the exemplary embodiment of the present disclosure is configured by an image forming apparatus 10 and a terminal apparatus 20 that are connected to each other via a network 30 and a management server 50 that is connected to the image forming apparatus 10 via an Internet 40. The terminal apparatus 20 generates print data and transmits the generated print data to the image forming apparatus 10 via the network 30. The image forming apparatus 10 receives the print data transmitted from the terminal apparatus 20 and outputs an image corresponding to the print data on paper. In addition, the image forming apparatus 10 is an apparatus that is a so-called multifunction machine having a plurality of functions such as a print function, a scanning function, a copy function, and a facsimile function. Further, the management server 50 is an apparatus that is installed in a place different from a place where the image forming apparatus 10 is installed and manages various types of information of the image forming apparatus 10.

In various apparatuses, such as the image forming apparatus 10, that are operated by a commercial power supply, in some cases, it is necessary to connect an earth wire of an apparatus body to a D-class ground in order to prevent a human body from receiving an electric shock in a case where a leakage of electricity occurs. In particular, in an electronic apparatus using a single-phase 200-V alternating current power supply, a voltage generated in a case of a leakage of electricity is also increased. Therefore, it is more crucial to connect the earth wire of the apparatus body to the D-class ground. However, even in a case of a non-connection state in which the earth wire of the apparatus body is not connected to the D-class ground, the electronic apparatus is operated normally as long as the leakage of electricity does not occur. Therefore, it is difficult to ascertain whether or not the earth wire of the apparatus body is correctly connected to the D-class ground. In addition, in a case where the earth wire on the body side is incorrectly connected to a neutral wire of a single-phase three-wire system or a ground-side electric circuit of a three-phase three-wire system, there is a possibility that the ground voltage of the electronic apparatus will increase due to a neutral wire open phase failure, an insulation failure on the power supply facility side, or the like and thus an electric shock accident will occur.

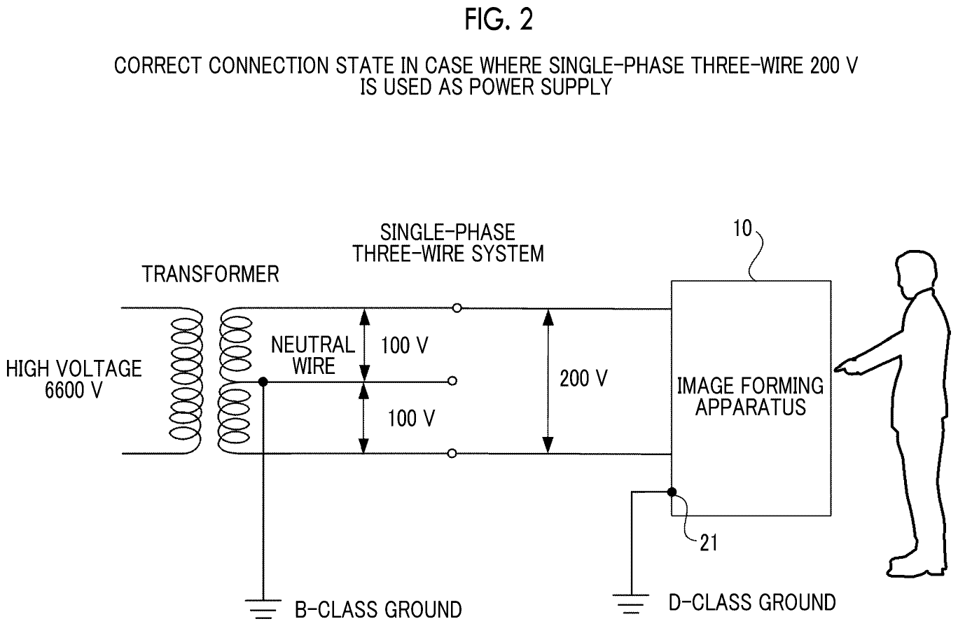

Hereinafter, a case will be described where the image forming apparatus 10 illustrated in FIG. 1 is an apparatus operated by a single-phase 200-V commercial power supply. FIG. 2 illustrates a correct connection state in a case where single-phase three-wire 200 V is used as a power supply.

FIG. 2 illustrates an aspect in which an earth wire 21 of the image forming apparatus 10 is correctly connected to the D-class ground and 200 V between two power wires excluding the neutral wire of the single-phase three-wire system is connected as the power supply.

In a single-phase three-wire electric circuit, the neutral wire is connected to a B-class ground on the secondary side in a case where a high voltage of 6600 V is stepped down by a transformer. The B-class ground is provided to prevent a high voltage from being applied to the low voltage side even in a case where the high voltage and the low voltage are mixed due to an internal failure of the transformer or the like and a high-voltage-side current flows to the low voltage side, thereby preventing a failure of a low-voltage-side electric apparatus or the like. Then, a power supply of 100 V can be drawn between the neutral wire and each of the two power wires, and a power supply of 200 V can be drawn between the two power wires.

In the correct connection state illustrated in FIG. 2, even in a case where a leakage of electricity occurs in the image forming apparatus 10, a leakage current flows to a metal frame, and the human body comes into contact with the metal frame, the leakage current flows to the D-class ground via the earth wire 21. Therefore, it is possible to prevent the human body from having an electric shock.

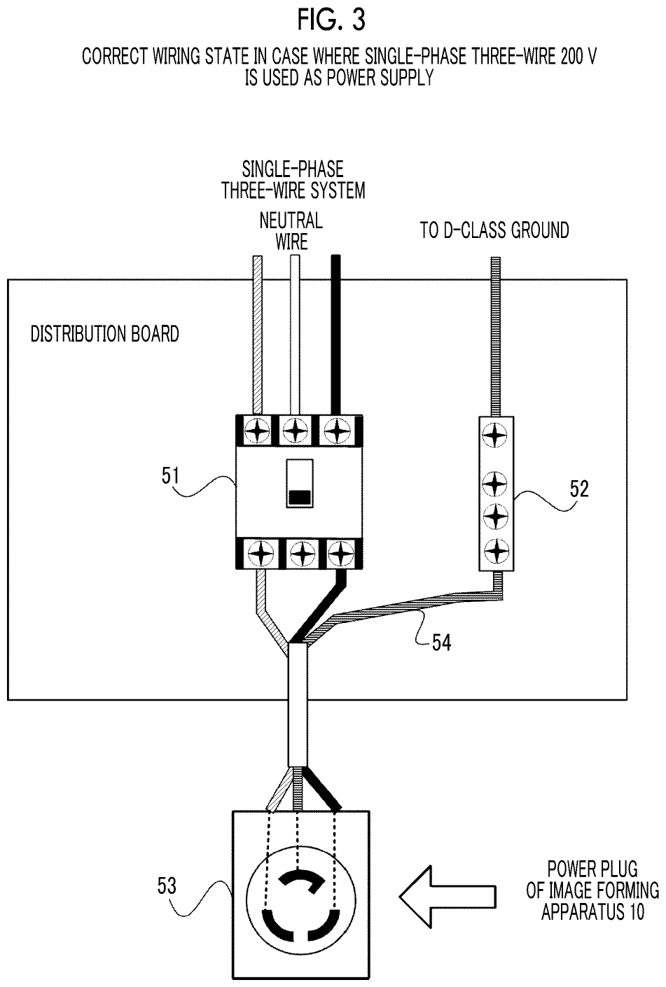

FIG. 3 illustrates a wiring state for implementing the correct connection state illustrated in FIG. 2. FIG. 3 illustrates a correct wiring state in a case where single-phase three-wire 200 V is used as the power supply.

In FIG. 3, a single-phase three-wire system is connected to a leakage breaker 51 of a distribution board, and two power wires excluding the neutral wire are connected to a 200-V outlet 53 for connecting the image forming apparatus 10. Then, an earth wire 54 is connected to an earth terminal 52 connected to the D-class ground. The earth wire 54 is connected to an earth terminal of the outlet 53.

In a case where a power plug of the image forming apparatus 10 is connected to the outlet 53 that is correctly wired in this way, the correct connection state illustrated in FIG. 2 is implemented.

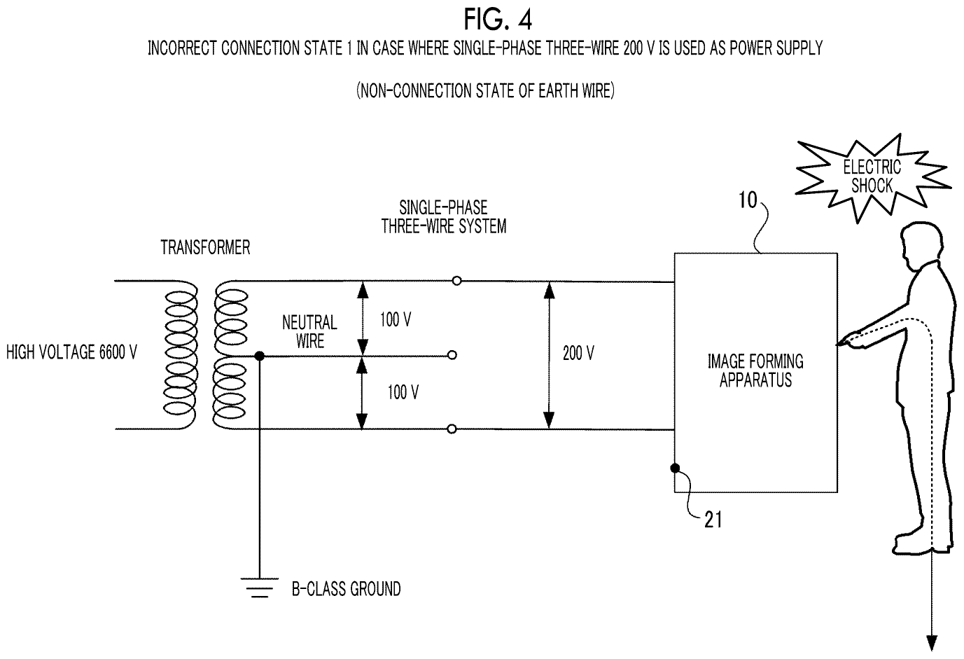

Next, an incorrect connection state in a case where single-phase three-wire 200 V is used as the power supply will be described with reference to FIGS. 4 to 7.

FIG. 4 is a diagram illustrating the non-connection state of the earth wire as an example of the incorrect connection state in a case where single-phase three-wire 200 V is used as the power supply. In FIG. 4, the earth wire 21 is in the non-connection state and is not connected to the D-class ground. Therefore, in a case where a leakage of electricity occurs in the image forming apparatus 10, a leakage current flows to the metal frame, and the human body comes into contact with the metal frame, there is a possibility that the leakage current will flow through the human body and the human body will receive an electric shock.

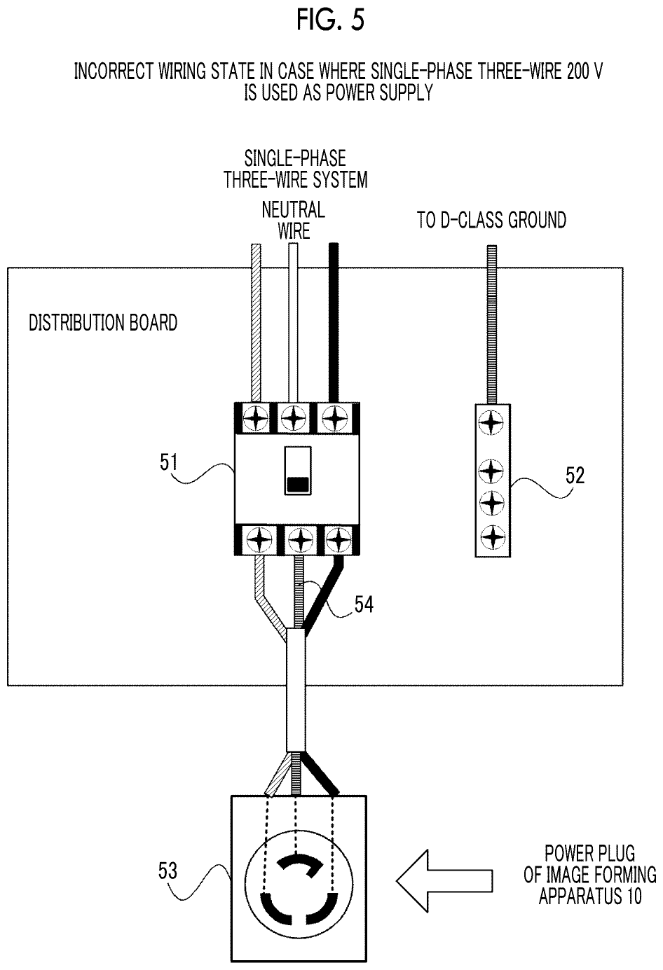

In addition, FIG. 5 illustrates an incorrect wiring state in a case where single-phase three-wire 200 V is used as the power supply.

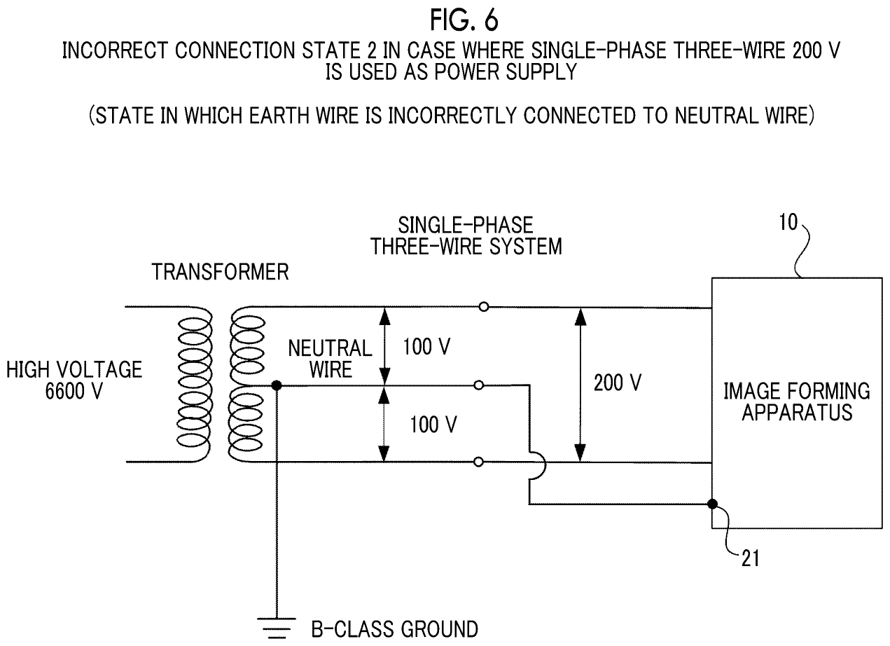

In FIG. 5, the earth wire 54 connected to the earth terminal of the outlet 53 is incorrectly connected to the neutral wire of the leakage breaker 51 as compared to the correct wiring state illustrated in FIG. 3. FIG. 6 illustrates a connection state in a case where the power plug of the image forming apparatus 10 is connected to the outlet 53. FIG. 6 is a diagram illustrating another example of the incorrect connection state in a case where single-phase three-wire 200 V is used as the power supply.

As can be seen from FIG. 6, the earth wire 21 of the image forming apparatus 10 is incorrectly connected to the neutral wire of the single-phase three-wire system. In a case where this incorrect connection is made, there is a possibility that an erroneous operation caused by noise or the like will occur. In the worst case, there is a possibility that the ground voltage of the metal frame of the image forming apparatus 10 will increase due to a neutral wire open phase failure and an electric shock accident will occur.

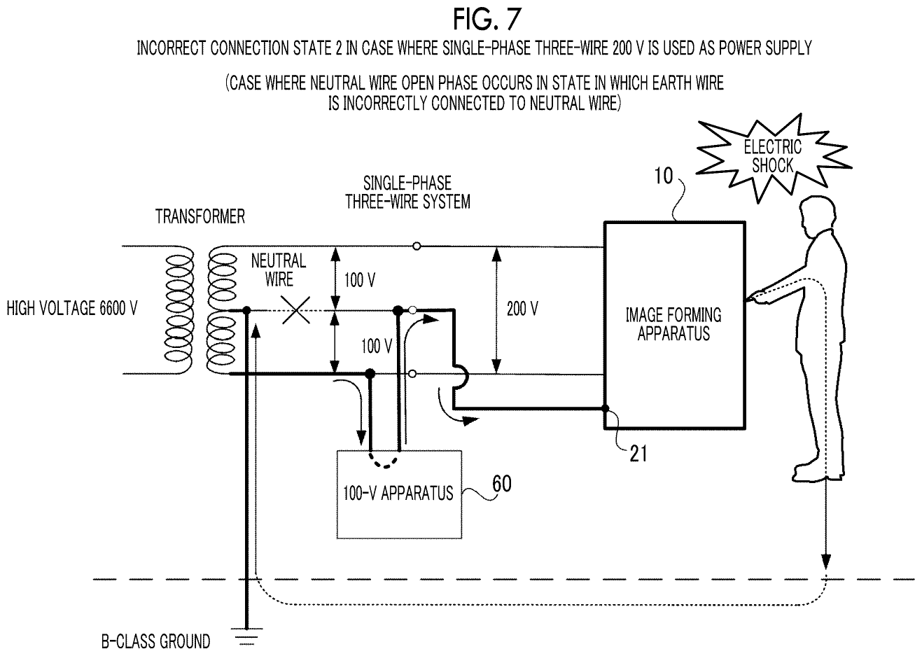

FIG. 7 illustrates an aspect in which a neutral wire open phase occurs in the incorrect connection state illustrated in FIG. 6.

FIG. 7 illustrates an aspect in which, in a case where the neutral wire is broken in the middle, an electric circuit is formed via another 100-V apparatus 60 that is connected between the neutral wire and one power wire and the human body in contact with the metal frame of the image forming apparatus 10 receives an electric shock.

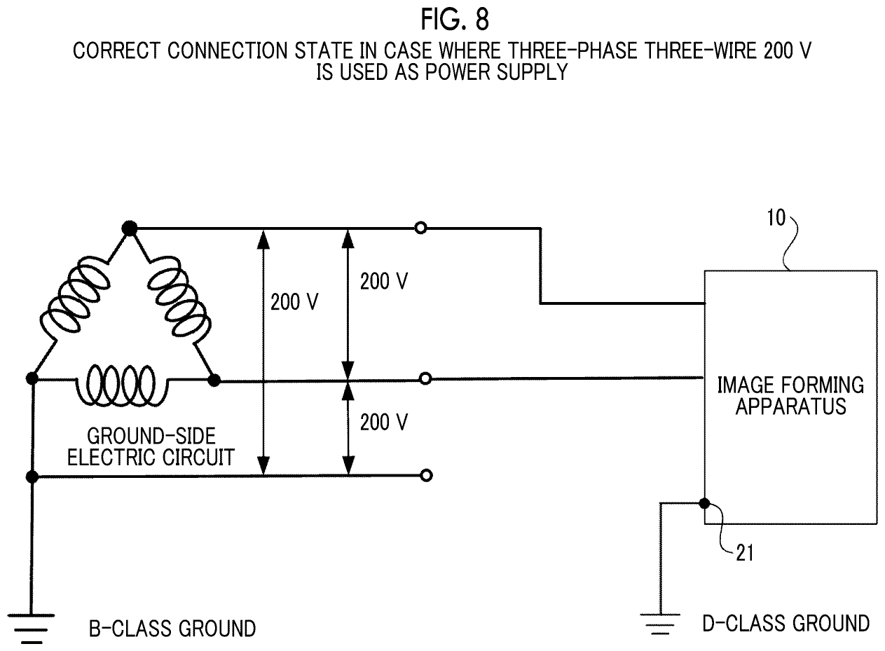

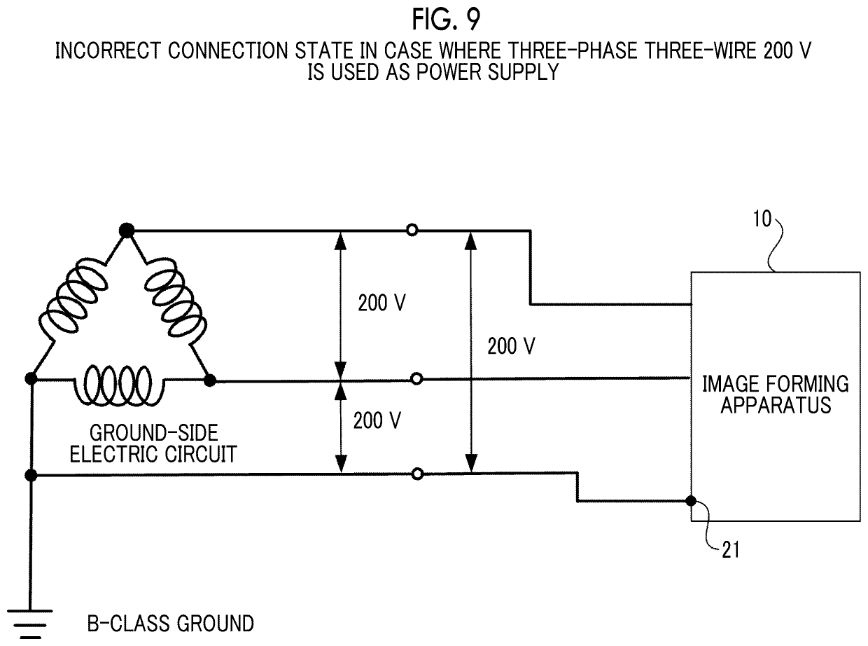

Next, a case where three-phase three-wire 200 V is used as the power supply for the image forming apparatus 10 will be described. In a three-phase three-wire electric circuit, one of three power wires is connected to the B-class ground. FIG. 8 is a diagram illustrating a correct connection state in a case where three-phase three-wire 200 V is used as the power supply. Referring to FIG. 8, an aspect is illustrated in which the earth wire 21 of the image forming apparatus 10 is connected to the D-class ground and 200 V between two power wires among three power wires of the three-phase three-wire system is connected as the power supply. FIG. 9 illustrates an incorrect connection state in a case where three-phase three-wire 200 V is used as the power supply. As can be seen from FIG. 9, the earth wire 21 of the image forming apparatus 10 is incorrectly connected to one power wire, which is a ground-side electric circuit, among three power wires. Even in a state where this incorrect connection is made, there is a possibility that an erroneous operation caused by noise or the like will occur. In the worst case, there is a possibility that the ground voltage of the metal frame of the image forming apparatus 10 will increase due to an insulation failure on the power supply facility side or the like and an electric shock accident will occur.

Therefore, in the image forming apparatus 10 according to the present exemplary embodiment, the following configuration makes it possible to ascertain whether or not the earth wire of the apparatus body is in the correct connection state.

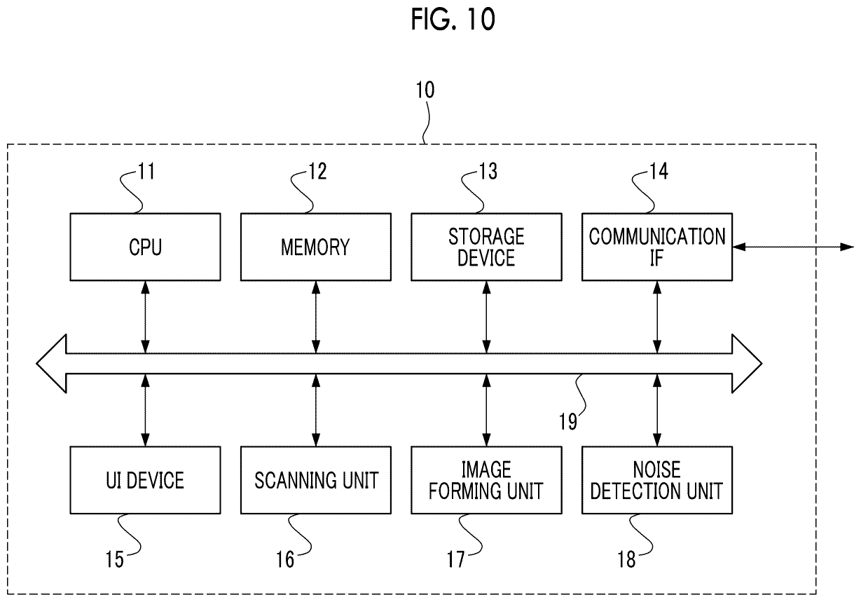

First, a hardware configuration of the image forming apparatus 10 according to the present exemplary embodiment is illustrated in FIG. 10.

As illustrated in FIG. 10, the image forming apparatus 10 has a CPU 11, a memory 12, a storage device 13, such as a hard disk drive, a communication interface (abbreviated to IF) 14 that transmits and receives data to and from an external apparatus or the like via the network 30, a user interface (abbreviated to UI) device 15 including a touch panel or a liquid crystal display and a keyboard, a scanning unit 16, an image forming unit 17, and a noise detection unit 18. These components are connected to one another via a control bus 19.

The CPU 11 is a processor that executes a predetermined process on the basis of a control program stored in the memory 12 or the storage device 13 to control the operation of the image forming apparatus 10. In addition, in the present exemplary embodiment, the configuration has been described in which the CPU 11 reads out the control program stored in the memory 12 or the storage device 13 and executes the control program. However, the present disclosure is not limited thereto. The control program may be provided in a form of being recorded on a computer readable recording medium. For example, this program may be provided in a form of being recorded on an optical disk, such as a compact disc (CD)-ROM or a digital versatile disc (DVD)-ROM, or in a form of being recorded on a semiconductor memory, such as a universal serial bus (USB) memory or a memory card. Further, this control program may be acquired from an external apparatus via a communication line connected to the communication interface 14. Furthermore, this control program may be provided as single application software or may be incorporated into software of each device of the image forming apparatus 10 as one function of the image forming apparatus 10.

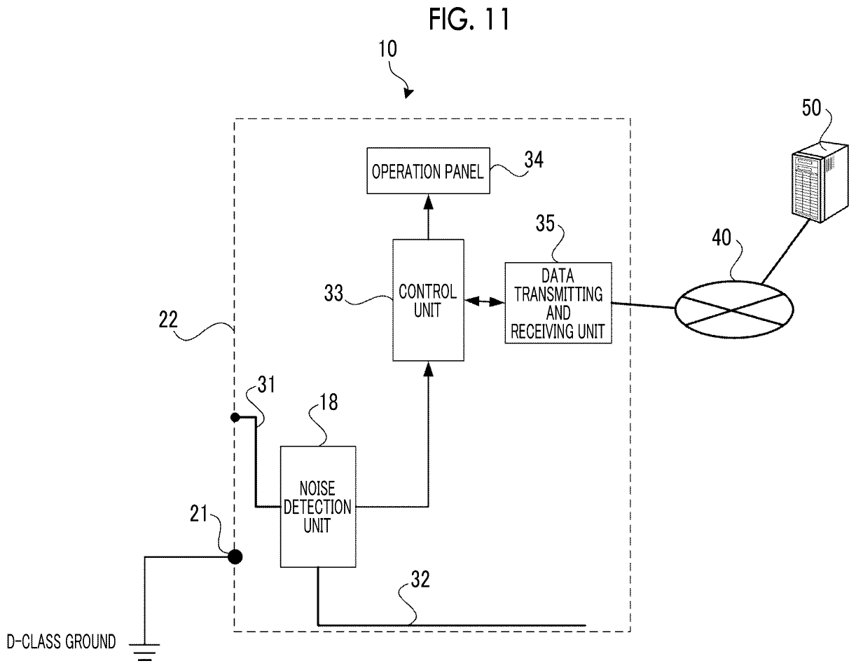

FIG. 11 is a block diagram illustrating a functional configuration of the image forming apparatus 10 implemented by executing the control program. In addition, in FIG. 11, only the configuration related to the function of ascertaining whether or not the earth wire is in the correct connection state is illustrated, and configurations related to the functions of printing, scanning, copying, and the like are omitted.

As illustrated in FIG. 11, the image forming apparatus 10 according to the present exemplary embodiment includes the noise detection unit 18, a control unit 33, an operation panel 34, and a data transmitting and receiving unit 35.

The data transmitting and receiving unit 35 transmits and receives data to and from an external apparatus, such as the management server 50, via the network, such as the Internet 40.

The control unit 33 controls the operation of the image forming apparatus 10 and displays various types of information for the user on the operation panel 34 or inputs information of various operations performed by the user from the operation panel 34. In addition, the control unit 33 transmits various types of information to the management server 50 via the data transmitting and receiving unit 35.

The noise detection unit 18 has two electric wires 31 and 32 and detects the magnitude of a noise component superimposed on the metal frame 22 of the apparatus body. Then, in a case where the magnitude of the noise component detected by the noise detection unit 18 exceeds a preset threshold value, the control unit 33 notifies that there is a possibility that the earth wire 21 will not be in the correct connection state.

Specifically, in a case where the magnitude of the noise component detected by the noise detection unit 18 exceeds the preset threshold value, the control unit 33 displays, on the operation panel 34, a message indicating that there is a possibility that the earth wire 21 will not be in the correct connection state. For example, in a case where the magnitude of the noise component detected by the noise detection unit 18 exceeds the preset threshold value, the control unit 33 displays, on the operation panel 34, any one or both of a message indicating that there is a possibility that the earth wire 21 will not be connected and a message indicating that there is a possibility that the earth wire 21 will be incorrectly connected to the neutral wire of the single-phase three-wire system or the ground-side electric circuit of the three-phase three-wire system.

Further, in a case where the magnitude of the noise component detected by the noise detection unit 18 exceeds the preset threshold value, the control unit 33 may notify a preset destination, for example, the management server 50 that there is a possibility that the earth wire 21 will not be in the correct connection state.

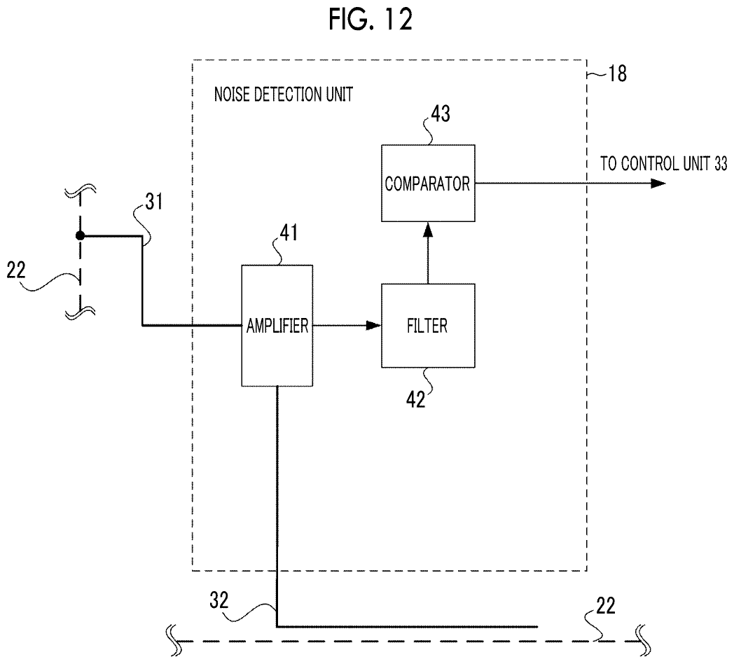

FIG. 12 illustrates a configuration of the noise detection unit 18 illustrated in FIG. 11. Referring to FIG. 12, the noise detection unit 18 includes the two electric wires 31 and 32, an amplifier 41, a filter 42, and a comparator 43.

The amplifier 41 amplifies a potential difference between the two electric wires 31 and 32. The filter 42 removes a direct-current component from the potential difference amplified by the amplifier 41. The comparator 43 determines whether or not the potential difference after passing through the filter 42 exceeds a preset threshold voltage and transmits a determination result to the control unit 33.

In addition, of the two electric wires 31 and 32, the electric wire 31 is connected to the metal frame 22 of the apparatus body, and the other electric wire 32 is provided to be drawn along the metal frame 22.

Since a current flows through the neutral wire of the single-phase three-wire system or the ground-side electric circuit of the three-phase three-wire system, there is a lot of noise in the neutral wire or the ground-side electric circuit. On the other hand, the amount of noise in the earth wire connected to the D-class ground is small. Therefore, in a case where the earth wire 21 is correctly connected to the D-class ground, the noise superimposed on the metal frame 22 of the apparatus body is also reduced.

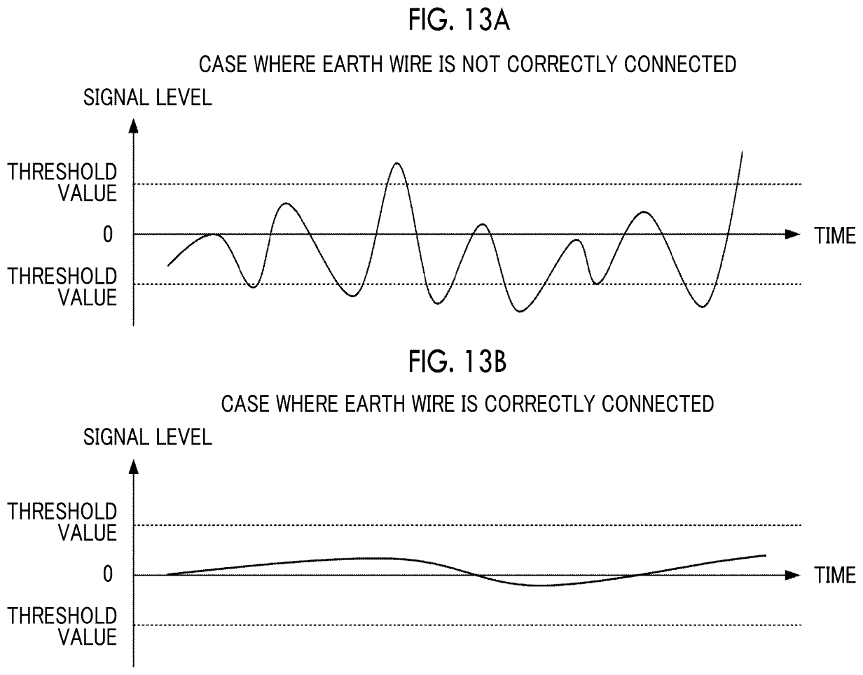

FIGS. 13A and 13B illustrate an aspect of the noise superimposed on the metal frame 22 in a case where the earth wire is not correctly connected and an aspect of the noise superimposed on the metal frame 22 in a case where the earth wire is correctly connected. FIG. 13A illustrates an example of the aspect of the noise superimposed on the metal frame 22 in a case where the earth wire is not correctly connected. As can be seen from FIG. 13A, a signal level of the noise exceeds a preset threshold value. In addition, FIG. 13B illustrates an example of the aspect of the noise superimposed on the metal frame 22 in a case where the earth wire is correctly connected. As can be seen from FIG. 13B, the signal level of the noise does not exceed the preset threshold value.

Therefore, the noise detection unit 18 detects the magnitude of the noise superimposed on the metal frame 22 of the apparatus body and determines whether or not the magnitude of the noise exceeds the preset threshold value to ascertain whether or not the earth wire 21 is in the correct connection state.

In addition, the control unit 33 acquires the determination result from the comparator 43 and determines whether or not the earth wire 21 is correctly grounded on the basis of, for example, the period for which the noise component exceeds the preset threshold value.

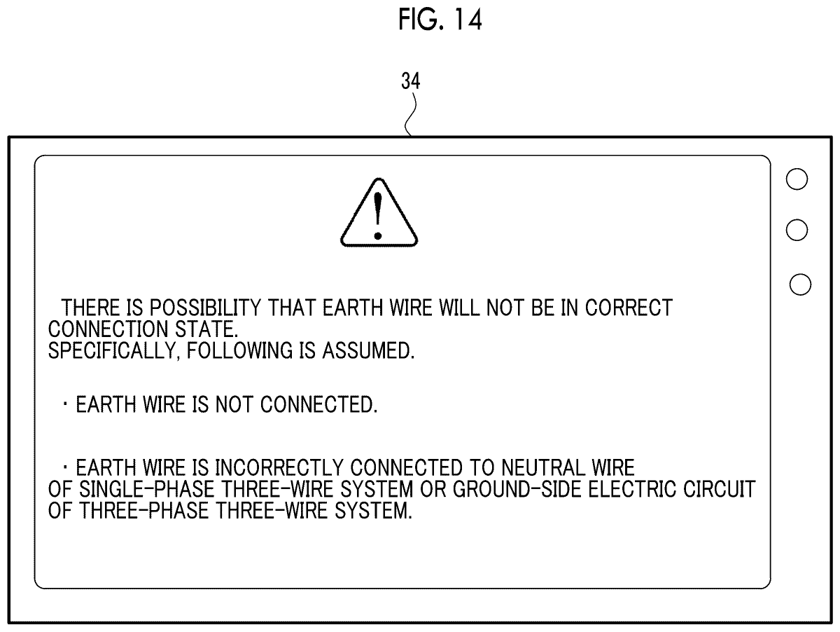

Then, in a case where the control unit 33 determines that there is a possibility that the earth wire 21 will not be in the correct connection state, for example, the control unit 33 displays a warning screen illustrated in FIG. 14 on the operation panel 34.

As can be seen from FIG. 14, a message “There is a possibility that the earth wire will not be in the correct connection state. Specifically, the following is assumed” is displayed on the operation panel 34. Then, it can be seen that, as a specific example in a case where the earth wire is not in the correct connection state, a message “The earth wire is not connected.” and a message “The earth wire is incorrectly connected to the neutral wire of the single-phase three-wire system or the ground-side electric circuit of the three-phase three-wire system.” are displayed on the operation panel 34.

It is expected that the user who sees this display will check the connection state of the earth wire 21 of the image forming apparatus 10 and notice the non-connection or incorrect connection of the earth wire 21.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

The term “system” in the present exemplary embodiment includes both a system configured by a plurality of apparatuses and a system configured by a single apparatus.

### Modification Examples

In the above-described exemplary embodiment, the image forming apparatus 10 has been described as an example of the electronic apparatus that is used with the earth wire connected thereto. However, the present disclosure is not limited thereto. The present disclosure can be similarly applied to any electronic apparatus, such as a microwave oven, a washing machine, or a refrigerator, as long as the electronic apparatus is used with the earth wire connected thereto.

### Supplementary Notes

Hereinafter, supplementary notes of the aspects of the present disclosure will be described.
(((1)))

An electronic apparatus comprising:
a detection unit that detects a magnitude of a noise component superimposed on a metal frame of an apparatus body; and
a processor configured to:
   notify that there is a possibility that an earth wire will not be in a correct connection state in a case where the magnitude of the noise component detected by the detection unit exceeds a preset threshold value.
(((2)))

The electronic apparatus according to (((1))), wherein the processor is configured to:
notify a preset destination that there is a possibility that the earth wire will not be in the correct connection state in a case where the magnitude of the noise component detected by the detection unit exceeds the preset threshold value.
(((3)))

The electronic apparatus according to (((1))), wherein the processor is configured to:
display, on an operation panel, a message indicating that there is a possibility that the earth wire will not be in the correct connection state in a case where the magnitude of the noise component detected by the detection unit exceeds the preset threshold value.
(((4)))

The electronic apparatus according to (((3))), wherein the processor is configured to:
display, on the operation panel, any one or both of a message indicating that there is a possibility that the earth wire will not be connected and a message indicating that there is a possibility that the earth wire will be incorrectly connected to a neutral wire of a single-phase three-wire system or to a ground-side electric circuit of a three-phase three-wire system in a case where the magnitude of the noise component detected by the detection unit exceeds the preset threshold value.
(((5)))

The electronic apparatus according to any one of (((1))) to (((4))),
wherein the detection unit includes:
two electric wires;
an amplifier that amplifies a potential difference between the two electric wires;
a filter that removes a direct-current component from the potential difference amplified by the amplifier; and
a comparator that determines whether or not the potential difference after passing through the filter exceeds a preset threshold voltage.
(((6)))

The electronic apparatus according to (((5))),
wherein one of the two electric wires is connected to the metal frame of the apparatus body, and
the other electric wire is provided to be drawn along the metal frame.
(((7)))

A program causing a computer to execute a process comprising:
receiving information indicating a magnitude of a noise component detected by a detection unit that detects the magnitude of the noise component superimposed on a metal frame of an apparatus body; and
notifying that there is a possibility that an earth wire is not in a correct connection state in a case where the magnitude of the noise component included in the received information exceeds a preset threshold value.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An electronic apparatus comprising:
a detection unit that detects a magnitude of a noise component superimposed on a metal frame of an apparatus body; and
a processor configured to:
notify that there is a possibility that an earth wire will not be in a correct connection state in a case where the magnitude of the noise component detected by the detection unit exceeds a preset threshold value.

2. The electronic apparatus according to claim 1, wherein the processor is configured to:
notify a preset destination that there is a possibility that the earth wire will not be in the correct connection state in a case where the magnitude of the noise component detected by the detection unit exceeds the preset threshold value.

3. The electronic apparatus according to claim 1, wherein the processor is configured to:
display, on an operation panel, a message indicating that there is a possibility that the earth wire will not be in the correct connection state in a case where the magnitude of the noise component detected by the detection unit exceeds the preset threshold value.

4. The electronic apparatus according to claim 3, wherein the processor is configured to:
display, on the operation panel, any one or both of a message indicating that there is a possibility that the earth wire will not be connected and a message indicating that there is a possibility that the earth wire will be incorrectly connected to a neutral wire of a single-phase three-wire system or to a ground-side electric circuit of a three-phase three-wire system in a case where the magnitude of the noise component detected by the detection unit exceeds the preset threshold value.

5. The electronic apparatus according to claim 1,
wherein the detection unit includes:
two electric wires;
an amplifier that amplifies a potential difference between the two electric wires;
a filter that removes a direct-current component from the potential difference amplified by the amplifier; and
a comparator that determines whether or not the potential difference after passing through the filter exceeds a preset threshold voltage.

6. The electronic apparatus according to claim 5,
wherein one of the two electric wires is connected to the metal frame of the apparatus body, and
the other electric wire is provided to be drawn along the metal frame.

7. A non-transitory computer readable medium storing a program causing a computer to execute a process comprising:
receiving information indicating a magnitude of a noise component detected by a detection unit that detects the magnitude of the noise component superimposed on a metal frame of an apparatus body; and
notifying that there is a possibility that an earth wire is not in a correct connection state in a case where the magnitude of the noise component included in the received information exceeds a preset threshold value.

8. A method comprising:
receiving information indicating a magnitude of a noise component detected by a detection unit that detects the magnitude of the noise component superimposed on a metal frame of an apparatus body; and
notifying that there is a possibility that an earth wire is not in a correct connection state in a case where the magnitude of the noise component included in the received information exceeds a preset threshold value.
